(19) United States
(12) Patent Application Publication
(10) Pub. No.: US 2018/0353976 A1
(43) Pub. Date: Dec. 13, 2018

(54) METHOD FOR MANUFACTURING TOOL OR CORRESPONDING PRODUCT

(71) Applicant: AKAAN TYÖVÄLINEPALVELU OY, Akaa (FI)

(72) Inventor: Jari MÄKINEN, Akaa (FI)

(73) Assignee: AKAAN TYÖVÄLINEPALVELU OY, Akaa (FI)

(21) Appl. No.: 15/776,015

(22) PCT Filed: Nov. 10, 2016
(86) PCT No.: PCT/FI2016/050794

§ 371 Date: May 14, 2018

(30) Foreign Application Priority Data
Nov. 13, 2015 (FI) 20150324

(51) Int. Cl. B05B 1/00; B23P 15/00; B65H 57/16; B29D 30/00

(52) U.S. Cl. CPC B05B 1/00; B23P 15/00; B65H 2801/93; B29D 30/00; B23P 2700/50; B65H 57/16

(57) ABSTRACT

A method for manufacturing a tool, liquid nozzle or corresponding product, in which one or more holes or openings of a desired shape are made into the product during manufacture. The hole or opening is required to have at least one of the following characteristics: interchangeability, serviceability, processability or mechanical wear-resistance, and to achieve this, the inner surface of the hole or opening is accessible in an appropriate manner. The product is divided into at least two parts with the dividing line arranged to run through the hole or opening in such a manner that in the product parts the hole or opening is open, such as an open groove, in which case it is freely accessible in each part.

The invention relates to a method for manufacturing a tool, liquid nozzle or corresponding product, in which method one or more holes or openings of a desired shape are made into the product during manufacture, and when using said product, said hole or opening is required to have at least one of the following characteristics: interchangeability, serviceability, processability or mechanical wear-resistance, and to achieve this, the inner surface of said hole or opening is accessible in an appropriate manner.

Tools and products according to the above introduction are previously known, in which the inner diameter of the holes and openings is so large that the product can be depth-hardened in such a manner that the inner surface of the hole also hardens. The size of the holes has also permitted the hard chromium plating, hard-coating or plasma-coating of their inner surfaces, when a required wear-resistance is obtained for the inner surface.

If the tool comprises holes that are small in diameter, such as less than 5 mm, and over 20 mm, for instance, in length, it has been possible earlier to make them of hardened preforms by making the holes by spark machining instead of drilling, for example, but processing their inner surfaces by hard-coating and plasma-coating, such as DVD-, CVD-, PACVD-coating, is afterwards impossible. The method of the present invention is directed to tools and products, which have holes of this type having small diameters but requiring wear-resistance and with no means to do the coating afterward.

A new method has now been developed to remove this draw-back and to solve the problem. The method of the invention is characterised in that the product is divided into at least two parts with the dividing line arranged to run through said hole or opening in such a manner that in the product parts, the hole or opening is open, such as an open groove, in which case it is freely accessible in each part.

The invention provides the advantage that even holes and openings that are small in diameter can be processed on their inner surface like other open surfaces, when they are made accessible to a required extent according to the invention. Thanks to the invention, even small holes of tools and nozzles, such as holes with a diameter of 0.2 to 5.0 mm, requiring wear-resistance can be hard-coated in all known manners.

Splitting the tool into two or more parts by means of a dividing line running through the holes provides on the inner surface of the holes joints that may affect the function of the holes in some applications. In the method of the invention, the joint lines of the parts are on the sides of the holes, which are susceptible to minor wear, when steel wires are led through the holes and the holes are used as guides for the steel wires to adjust mainly the relative sideways distance between the wires.

In the following, the invention will be described in greater detail with reference to the attached drawing, in which

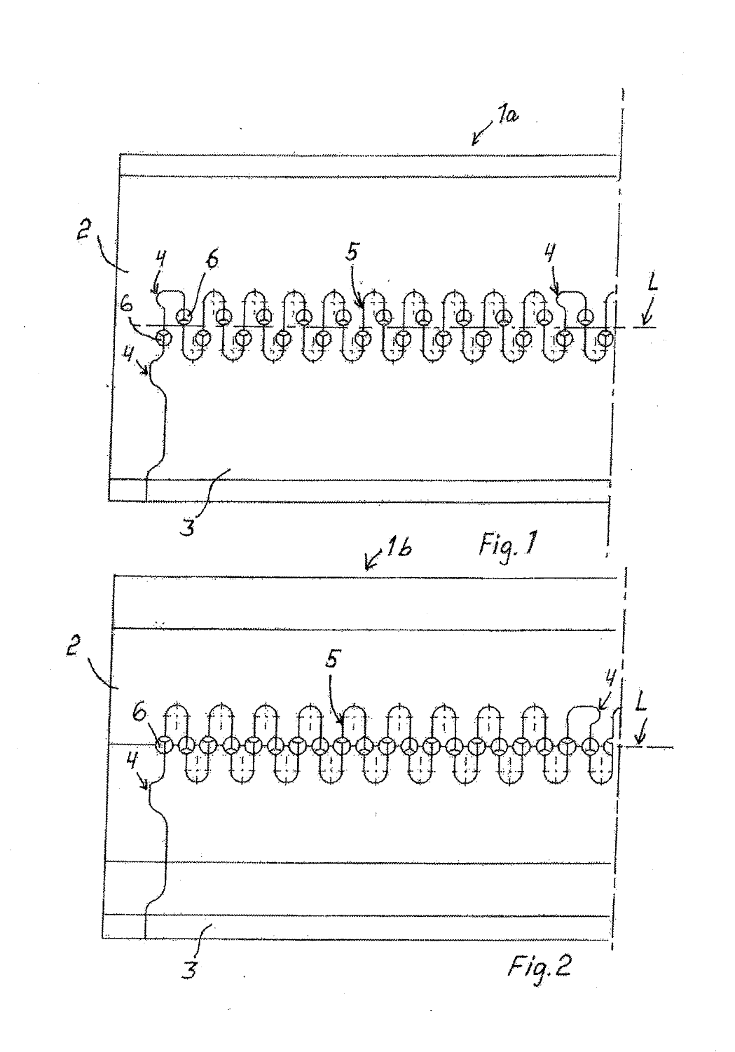

FIG. 1 shows a steel wire guide unit as seen from the direction of the holes,

FIG. 2 shows a guide unit, in which the holes are side-by-side in a direct line,

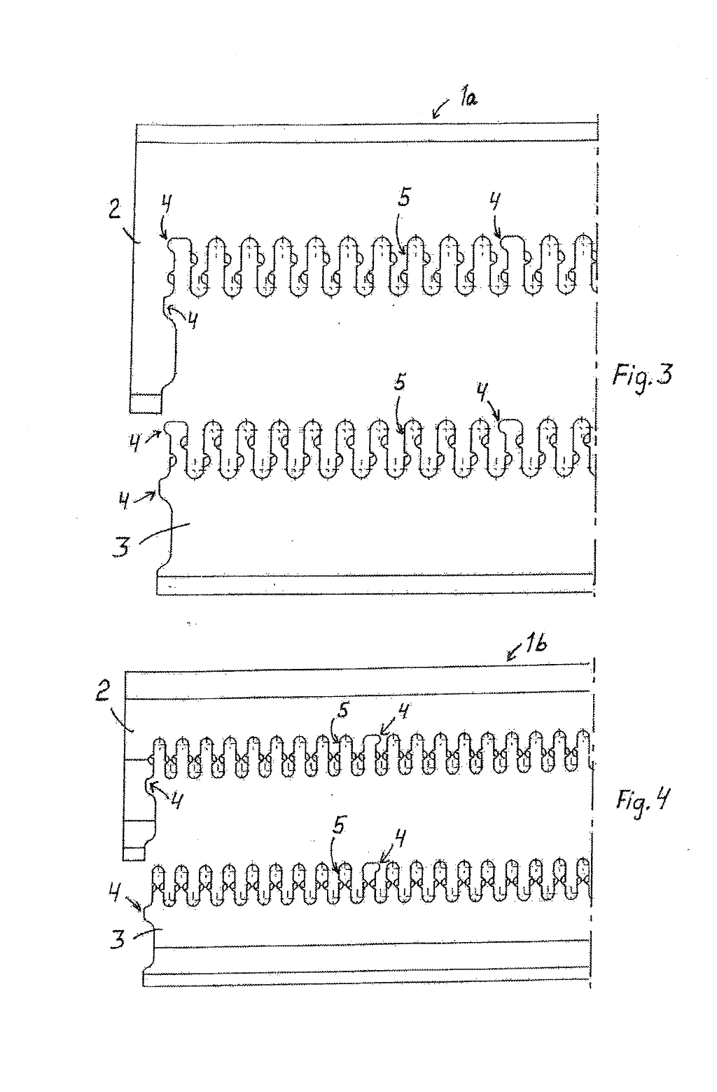

FIG. 3 shows the unit of FIG. 1 with the parts detached,

FIG. 4 shows the unit of FIG. 2 with the parts detached,

FIG. 5 is an oblique view of the unit of FIG. 3 with the parts detached, and

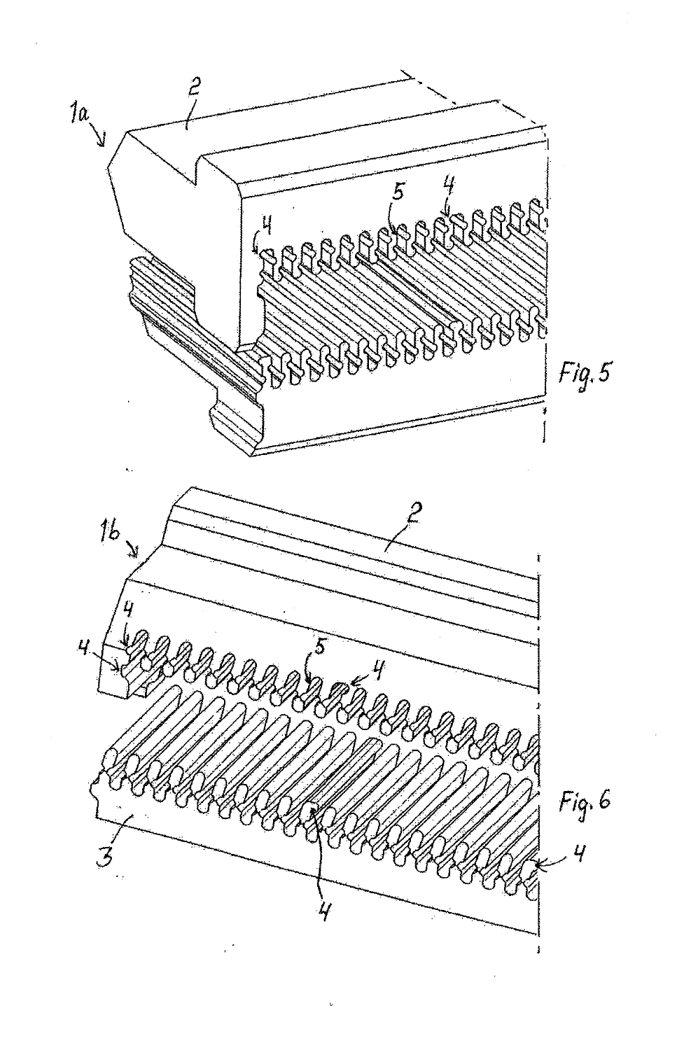

FIG. 6 is an oblique view of the unit of FIG. 4 with the parts detached.

The method of the invention is described using the example of FIG. 1, which relates to the manufacture of vehicle tyres, where a guide tool is required to feed thin steel wires forming a steel web in a tyre. FIG. 1 shows the left side of a symmetrical tool la. The tool 1a comprises a row of holes evenly distributed in a zigzag form, in which the diameters of the holes 6 are less than 1 mm. Thin steel wires are led through the holes 6 in the tool 1a inside a rubber mixture to form a metal web of the tyre. The tool 1a is divided into two parts 2 and 3 through a dividing plane L that is horizontal in FIG. 1. The dividing line 5, instead, runs in a waveform comprising vertical portions, where the dividing line 5 runs through the holes 6. The dividing line 5 extends from one edge of the tool la to another and forms the dividing plane L, the parts 2 and 3 of which are detachable from each other.

The dividing line 5 runs through the holes 6 preferably symmetrically in the middle, whereby the grooves forming the holes 6 in the parts 2 and 3 are semi-circular profiles that are needed to guide a round wire.

Direct detachment of the parts 2, 3 from each other is prevented by sideways deviations 4 added at some points of the waveform. The start and end parts of the dividing line 5 also contain corresponding deviations 4 that prevent the direct detachment of the parts 2, 3 from each other. The deviation may also be a rectangular profile. The parts 2 and 3 can be separated from each other by sliding the parts 2, 3 in relation to each other in the direction of the holes 6 until they detach.

In the example of FIG. 2, all adjacent holes 6 are on the same line. In spite of this, the dividing line 5 still has a waveform. In this case, too, the dividing line 5 runs vertically at the holes 6, even though the dividing plane L is substantially horizontal.

FIGS. 3 to 6 show the parts 2, 3 of the examples of FIGS. 1 and 2 separate. The parts 2, 3 are made by precision work using wire spark machining. The parts 2, 3 can be hardened preforms, into which the waveforms and holes, or as in this case hole halves, are made using wire spark machining. Hard-coatings can be made in different ways to the inner surfaces of the hole 6 halves in the separate parts 2 and 3.

It is previously known to make small holes that are less than 2 mm, for instance, by drilling them into a uniform preform before hardening. It is also possible to make small holes in a uniform hardened preform by spark machining. The small holes made into a uniform preform in the above-mentioned ways cannot, however, be hard-coated afterward. The splitting of the tool according to the invention and providing small holes as hole halves makes it possible to coat the inner surfaces of the holes afterward. A damaged part can also be replaced with a new one.

The method of the invention can be applied to all industrial products, in which the guidance of wires and fibres or liquid flows, such as liquids used in nozzle units with a small diameter or high-pressure liquids, is needed. In a nozzle split according to the method, the wear surfaces can be easily accessed and coated or replaced.

In an embodiment, other cross-sectional profiles than a round hole are also needed. These profiles may include a rectangle, square, oval and, especially in liquid nozzles, a slotted cross-sectional profile having a length considerably bigger, for instance 10 times bigger, than the width.

In an embodiment, the parts are not only as top and bottom parts, but also side by side in the lateral direction, whereby replacement parts become smaller units.
cm 1-8. (canceled)

9. A method for manufacturing a tool, a liquid nozzle or a corresponding product, the method comprising:
making one or more holes or openings of a desired shape into the product during manufacture, said hole or opening having at least one of the following characteristics when in use: interchangeability, serviceablity, processability or mechanical wear-resistance, with an inner surface of said hole or opening being accessible; and
dividing the tool, liquid nozzle or product into at least two parts with a dividing line arranged to run through said hole or opening such that in the two parts, the hole or opening is open to be accessible in each of the two parts, the dividing line being arranged to cross the hole/opening in a direction that is different to a direction in which the tool, liquid nozzle or product splits/opens into the two parts or in a direction that is different to a direction of an actual dividing plane of a row of holes/openings in the tool, liquid nozzle or product.

10. A method as claimed in claim 9, wherein there are several holes/openings, and their inner diameter is less than 5 mm to prevent hard-coating or plasmaspraying of their inner surfaces when they are holes in a uniform product.

11. A method as claimed in claim 9, wherein the dividing line runs through a middle of the hole/opening, dividing the hole/opening symmetrically into two parts.

12. A method as claimed in claim 9, wherein the dividing line is, in a case of plural side-by-side holes/openings, arranged to run perpendicular to an actual dividing plane at each hole/opening as it advances alternately back and forth to form an actual waveform dividing line.

13. A method as claimed in claim 9, comprising:
forming locking forms in the dividing line to prevent the dividing plane from opening perpendicularly in a direction of the dividing plane, and arranging a specific sideways deviation as the locking form.

14. A tool, a liquid nozzle or a corresponding product comprising:
one or more holes or openings of a desired shape made during manufacture to have at least one of the following characteristics when in use: interchangeability, serviceablity, processability or mechanical wear-resistance, with an inner surface of said hole or opening being accessible; and
a dividing line by which the tool, liquid nozzle or product is divided into at least two parts, the dividing line being arranged to run through said hole or opening such that in the two parts, the hole or opening is open to be accessible in each part, and the dividing line is arranged to cross the hole/opening in a direction that is different to a direction in which the tool, liquid nozzle or product splits/opens into the two parts or in a direction that is different to a direction of an actual dividing plane of a row of holes/openings in the tool, liquid nozzle or product.

15. A tool, liquid nozzle or corresponding product as claimed in claim 14, wherein the dividing line is arranged to run through a middle of the hole/opening and to divide the hole/opening symmetrically into two parts.

16. A tool, liquid nozzle or corresponding product as claimed in claim 14, comprising:
locking forms formed in the dividing line to prevent a dividing plane from opening perpendicularly in a direction of the dividing plane, a specific sideways deviation configured in a waveform or square being arranged as the locking form.
